(19) United States
(12) Patent Application Publication
(10) Pub. No.: US 2012/0153506 A1
(43) Pub. Date: Jun. 21, 2012

(54) WIRING SUBSTRATE AND SEMICONDUCTOR DEVICE, AND METHOD OF MANUFACTURING SEMICONDUCTOR DEVICE

(75) Inventor: Yoshihiro MACHIDA, Nagano (JP)

(73) Assignee: SHINKO ELECTRIC INDUSTRIES CO., LTD., Nagano-shi (JP)

(21) Appl. No.: 13/329,582

(22) Filed: Dec. 19, 2011

(30) Foreign Application Priority Data
Dec. 21, 2010 (JP) 2010-284917

(51) Int. Cl. H01L 23/498; H05K 1/11; H01L 21/56

(52) U.S. Cl. 257/778; 438/108; 174/261; 257/E23.06; 257/E21.502

(57) ABSTRACT

A wiring substrate includes a plurality of connection pads, and a protection insulating layer in which opening portion exposing said plurality of connection pads collectively is provided, wherein a notched opening portion is provided to a sidewall of the opening portion of the protection insulating layer in area between said plurality of connection pads. When a semiconductor chip is flip-chip connected to the connection pads by the prior sealing technology, a void occurring in the sealing resin is trapped in the notched opening portion.

### CROSS-REFERENCE TO RELATED APPLICATIONS

This application is based upon and claims the benefit of priority of the prior Japanese Patent Application No. 2010-284917, filed on Dec. 21, 2010, the entire contents of which are incorporated herein by reference.

### FIELD

It is related to a wiring substrate and a semiconductor device, and a method of manufacturing a semiconductor device.

### BACKGROUND

In the prior art, there is a wiring substrate on which a semiconductor chip is flip-chip mounted. In such wiring substrate, a solder resist in which opening portions are provided so as to expose the connection pads is formed, and a solder layer, or the like is formed on the connection pads. Then, the bump electrodes of the semiconductor chip are flip-chip connected onto the connection pads of the wiring substrate.

In recent years, for the purpose of reducing the number of steps, the prior sealing technology has been developed. According to this prior sealing technology, before the semiconductor chip is mounted, a sealing resin is formed on the wiring substrate, and then the bump electrodes of the semiconductor chip is pushed into the sealing resin, thereby the semiconductor chip is flip-chip mounted on the wiring substrate and is sealed with the sealing resin.

A related art is disclosed in Japanese Laid-open Patent Publication No. 2007-142037 and Japanese Laid-open Patent Publication No. 2007-227708.

As explained in the preliminary matter described later, when a narrower pitch of the connection pads of the wiring substrate is advanced, it becomes difficult to arrange independently the opening portions of the solder resist on each connection pad respectively. For this reason, the solder resist which has opening portions each formed like a frame shape, or the like so as to collectively expose a plurality of connection pads is formed.

When the semiconductor chip is flip-chip connected onto the connection pads of such wiring substrate by using the prior sealing technology describe above, voids of the sealing resin are easy to occur at level difference parts of the connection pads which are arranged to the sidewalls of the opening portions in the solder resist.

The voids of the sealing resin are produced in contact with the connection pads. Therefore, copper migration is easily caused in the connection pads when a reliability test is applied, and thus enough reliability can not be obtained. Also, in the case that the connection pads on the surface side of which a solder layer is formed are used, a solder is moved into the voids at reflow heating. As a result, there is a risk of causing an electric short-circuit between the connection pads, it becomes a factor of the reduction in the yield.

### SUMMARY

According to one aspect discussed herein, there is provided a wiring substrate, which includes a plurality of connection pads, and a protection insulating layer in which opening portion exposing said plurality of connection pads collectively is provided, wherein a notched opening portion is provided to a sidewall of the opening portion of the protection insulating layer in area between said plurality of connection pads.

According to another aspect discussed herein, there is provided a semiconductor device, which includes the wiring substrate described above, a semiconductor chip flip-chip connected to the connection pads P of the wiring substrate, and a sealing resin filled between the semiconductor chip and the wiring substrate.

According to still another aspect discussed herein, there is provided a method of manufacturing a semiconductor device, which includes forming a sealing resin material on a wiring substrate, the wiring substrate including a plurality of connection pads, and a protection insulating layer in which opening portion exposing said plurality of connection pads collectively is provided, and the wiring substrate in which a notched opening portion is provided to a sidewall of the opening portion in the protection insulating layer in area between said plurality of connection pads; and pushing bump electrodes of a semiconductor chip into the sealing resin material to flip-chip connect the bump electrodes to the connection pads, and filling a sealing resin formed of the sealing resin material under the semiconductor chip.

### BRIEF DESCRIPTION OF THE DRAWINGS

FIG. 1 is a partially plan view depicting a wiring substrate in the preliminary matter;

FIG. 2 is a sectional view depicting a state that a semiconductor chip is flip-chip connected to the wiring substrate (FIG. 1) by the prior sealing technology;

FIG. 3 is a sectional view and a plan view depicting such a situation that voids occur in a sealing resin when the semiconductor chip is flip-chip connected to the wiring substrate (FIG. 1) by the prior sealing technology;

FIG. 4 is plan views depicting a wiring substrate according to the embodiment;

FIG. 5 is a sectional view depicting a state that a semiconductor chip is mounted onto the wiring substrate (FIG. 4) by the prior sealing technology according to the embodiment;

FIG. 6 is a sectional view and a plan view depicting a semiconductor device according to the embodiment; and

FIG. 7 is a partially enlarged sectional view and a partially enlarged plan view of FIG. 6 depicting such a situation that voids of the sealing resin are trapped in notched opening portions of a solder resist.

### DESCRIPTION OF EMBODIMENTS

An embodiment will be explained with reference to the accompanying drawings hereinafter.

Prior to the explanation of the present embodiment, the preliminary matter to be set forth as a basis will be explained hereunder.

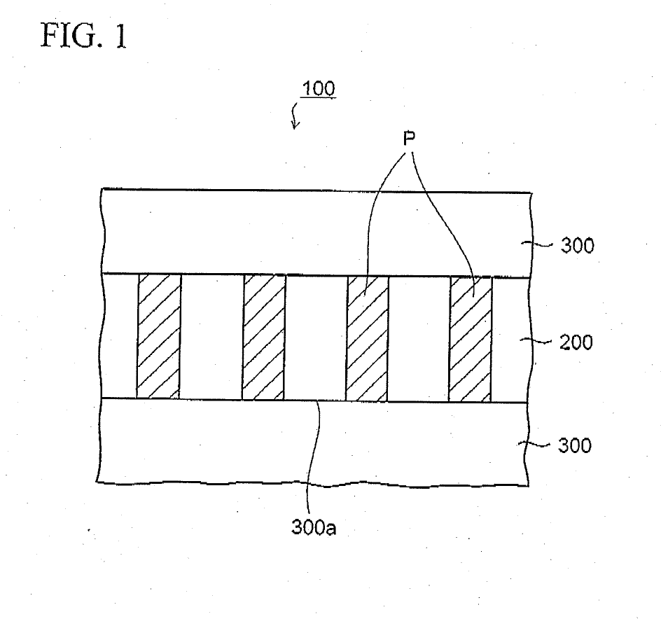

As depicted in FIG. 1, in a wiring substrate 100 in the preliminary matter, a plurality of connection pads P are arranged side by side on an interlayer insulating layer 200. Although not depicted particularly, a required multilayer wiring is formed under the interlayer insulating layer 200, and the connection pads P are connected to the multilayer wiring via via holes (via conductors).

A solder resist 300 in which opening portions 300a which collectively expose a plurality of connection pads P are provided, is formed on the interlayer insulating layer 200.

In FIG. 1, a part of the wiring substrate is depicted. The connection pads P are arranged side by side on four sides, i.e., the upper and lower sides and the right and left sides of the wiring substrate. The opening portions 300a of the solder resist 300 are arranged to be connected like a frame.

When an arrangement pitch in the connection pads P is narrowing (an arrangement pitch: 50 μm or less, for example), it becomes difficult to arrange individually the opening portions 300a of the solder resist 300 on the connection pads P respectively. Therefore, as described above, the solder resist 300 in which the opening portions 300a which collectively expose a plurality of connection pads P are provided is employed.

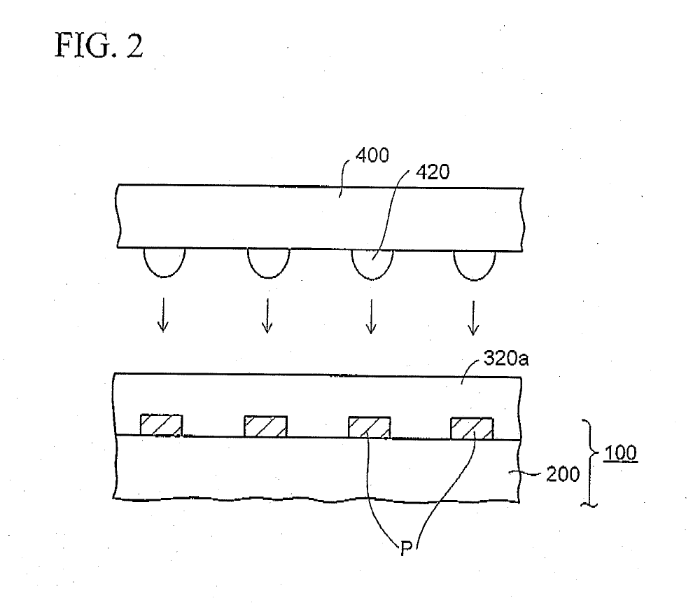

Then, as depicted in FIG. 2, a sealing resin material 320a is formed on the wiring substrate 100 in FIG. 1, and bump electrodes 420 of a semiconductor chip 400 are pushed into the sealing resin material 320a. Then, by applying the heating process, the bump electrodes 420 of the semiconductor chip 400 are pressure-welded to the connection pads P of the wiring substrate 100 and are connected it.

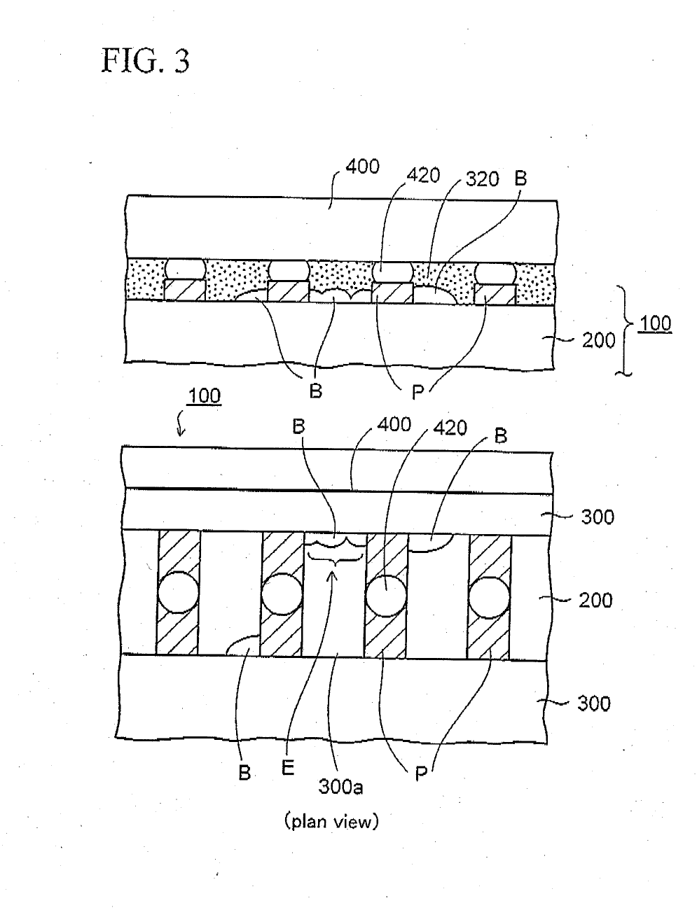

By this matter, as depicted in FIG. 3, the sealing resin material 320a is cured simultaneously, and a cured sealing resin 320 is filled into a clearance under the semiconductor chip 400. In a plan view in FIG. 3, the semiconductor chip 400 and the bump electrodes 420 are depicted in a perspective view.

At this time, as depicted in FIG. 3, in the case that the prior sealing technology described above is employed, air bubbles are easily take in the sealing resin material 320a at the time when the semiconductor chip 400 is pushed into the sealing resin material 320a and is flip-chip connected. Then the air bubbles taken in the sealing resin material 320a are trapped in the level difference parts of the connection pads P, which are arranged to the sidewalls of the opening portions 300a of the solder resist 300, and remain as voids B.

In such situation, when the HAST (Highly Accelerated temperature and humidity Stress Test) that is the pressurization hygroscopicity voltage impression test, the copper migration of the connection pad P occurs easily because the void B contacts the connection pad P. Therefore, enough reliability of the electrical connection to the semiconductor chip 400 cannot be obtained.

Also, there is a case that a solder layer is formed on the surface side of the connection pads P and the semiconductor chip 400 is flip-chip connected to the connection pads P by applying the reflow heating to the solder layer. In this case, when the void B occurs so as to contact the adjacent connection pads P (a part indicated by E in a plan view of FIG. 3), solder flows into the void B and cause an electric short-circuit between the adjacent connection pads P. It becomes a factor of the reduction in the yield.

Also, moisture and heat degradation components serving as an outgas at a time of heating exist in the wiring substrate 100. Accordingly, when the heating process is applied in flip-chip connecting the semiconductor chip 400, the outgas (water vapor, or the like) is generated from the wiring substrate 100. As a result, such outgas is trapped in the level difference part of the connection pad P, and then the void B occurs, thereby the similar problems are caused.

In an embodiment explained hereinafter, the disadvantages mentioned above can be solved.

### Embodiment

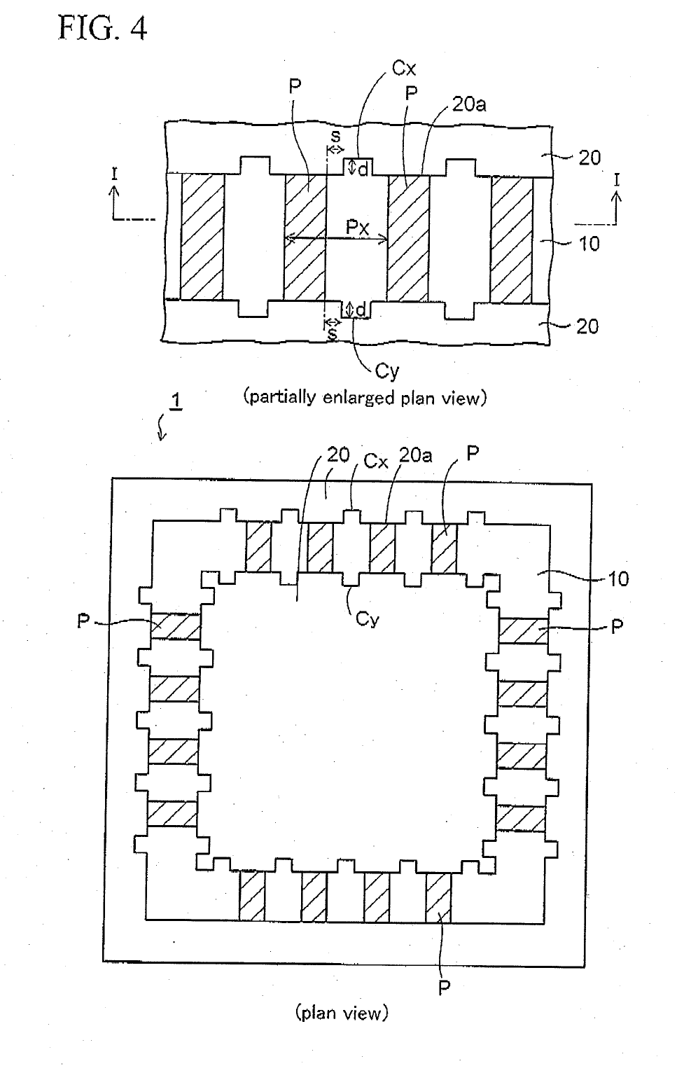

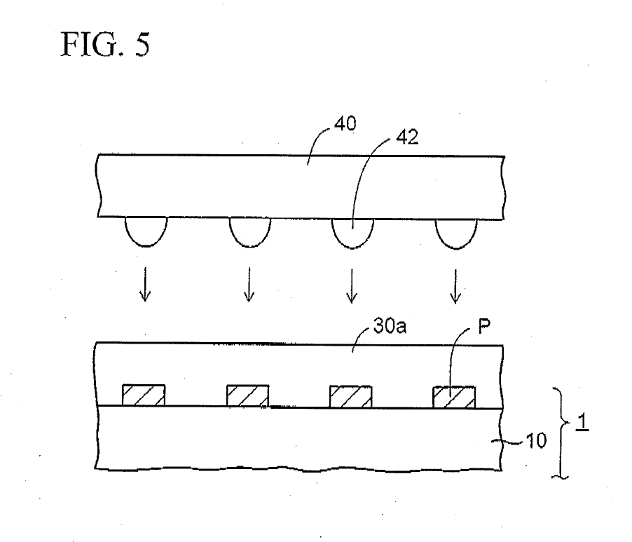

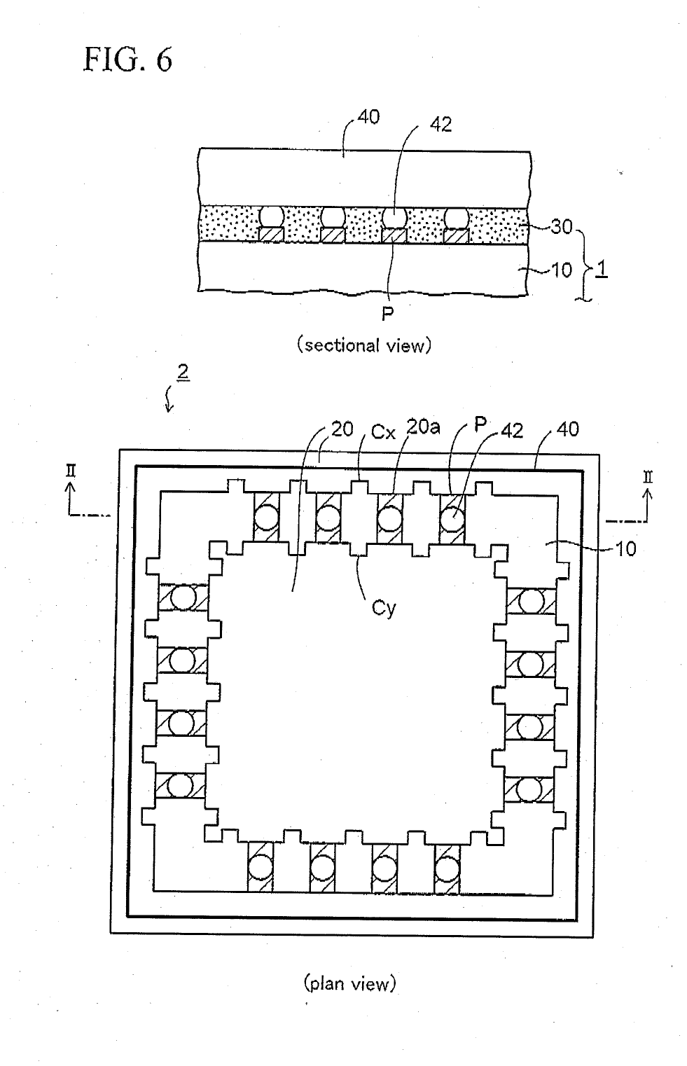

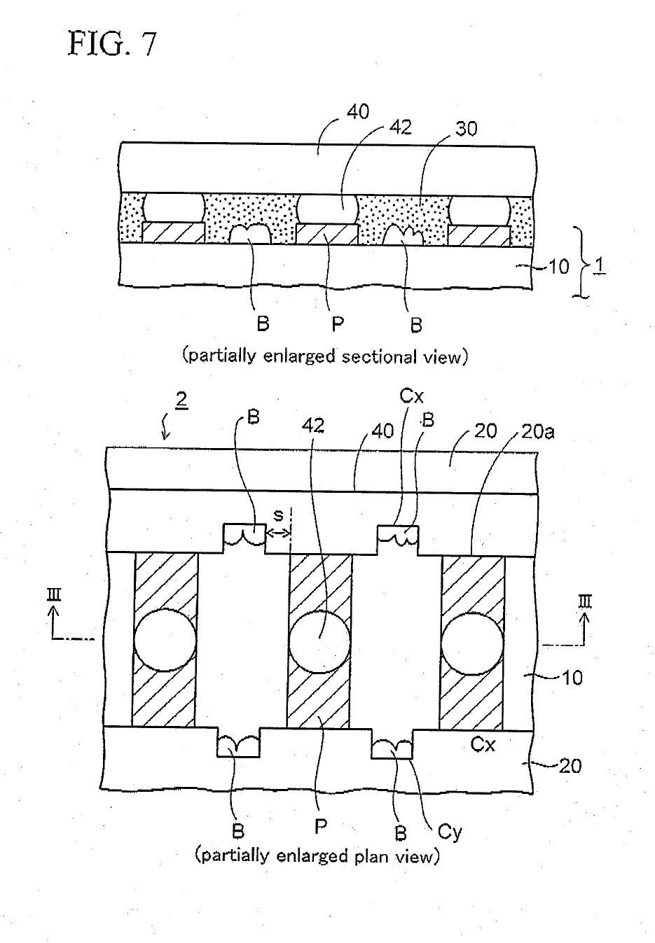

FIG. 4 is plan views depicting a wiring substrate according to an embodiment, FIG. 5 is a view depicting a state that a semiconductor chip is flip-chip connected onto the wiring substrate by the prior sealing technology according to the embodiment, and FIG. 6 and FIG. 7 are views depicting a semiconductor device according to the embodiment.

As depicted in FIG. 4, in a wiring substrate 1 of the embodiment, a plurality of connection pads P are arranged side bys side on an interlayer insulating layer 10. Although not depicted particularly, a required multilayer wiring is formed under the interlayer insulating layer 10, and the connection pads P are connected the multilayer wiring via via holes (via conductors).

The connection pads P may be connected to the leading wirings and may be arranged as connection wiring parts at their one end parts or their center parts, or may be arranged as an island-like pad electrode.

An arrangement pitch Px of the connection pads P is set in a range from 30 to 50 μm, for example, and a thickness of the connection pads P is set in arrange from 20 to 30 μm for example. Also, in an example of the present embodiment, the connection pad P is formed of a copper layer on the surface side of which a solder layer is formed. In this case, the connection pad P may be formed of a copper layer only, or various wiring materials can be used.

The connection pads P are arranged so as to align in belt-like areas each extended in the lateral direction on the upper and lower sides respectively, and are arranged so as to align in the belt-like areas each extended in the longitudinal direction on the right and left sides respectively. In this manner, the connection pads P are arranged side by side in the belt-like areas located on the peripheral sides in the four direction respectively.

Also, a solder resist 20 (protection insulating layer), in which frame-like opening portions 20a which collectively expose a plurality of connection pads P are provided, is formed on the interlayer insulating layer 10. The connection pads P are arranged perpendicularly to the extending direction of the opening portions 20a of the solder resist 20. A thickness of the solder resist 20 is set in a range from 20 to 50 μm, for example.

In this manner, in the present embodiment, the opening portions 20a of the solder resist 20 are arranged so as to expose a plurality of connection pads P collectively. This is because, as explained in the preliminary matter described above, when a narrower pitch of an arrangement pitch Px in the connection pads P is advanced (30 to 50 μm), it becomes difficult to arrange independently the opening portions 20a of the solder resist 20 on the connection pads P respectively.

Further, in the wiring substrate 1 of the present embodiment, in the both sidewalls of the opening portions 20a of the solder resist 20, first and second notched opening portions. Cx, Cy are provided in the areas between the connection pads P respectively.

The first notched opening portions Cx, each of which is dented from the sidewall to the outside horizontal direction, are provided to the sidewalls of the outside of the opening portions 20a of the solder resist 20. Also similarly, the second notched opening portions Cy, each of which is dented from the sidewall to the inside horizontal direction, are provided to the sidewalls of the inside of the opening portions 20a of the solder resist 20.

The opening portions 20a and the first and second notched opening portions Cx, Cy of the solder resist 20 are formed by patterning a photosensitive resin (a liquid resin or a resin film), or the like by means of the photolithography. Otherwise, the solder resist 20 may be formed by the screen printing. As the solder resist 20, an epoxy resin, a polyimide resin, or the like is used.

In the present embodiment, the solder resist 20 is illustrated as the protection insulating layer which is provided to the uppermost part of the wiring substrate 1. In this case, various insulating resins can be used.

As depicted in a partially enlarged plan view of FIG. 4, in the case that an arrangement pitch Px of the connection pads P is set to about 35 μm, a distance between the first and second notched opening portions Cx, Cy, and the connection pads P is set in a range from 5 to 10 μm, and also a depth d of the first and second notched opening portions Cx, Cy is set in a range from 5 to 10 μm.

As described later, the semiconductor chip is flip-chip connected to the connection pads P of the wiring substrate 1 by the prior sealing technology, and thus a clearance located under the semiconductor chip is sealed with a sealing resin. At that time, the voids occurred in the sealing resin are trapped in the first and second notched opening portions Cx, Cy.

The required distance s may be provided between opening positions of the first and second notched opening portions Cx, Cy in the solder resist 20 and the connection pads P, according to the arrangement pitch Px between the connection pads P, and the conditions of the flip-chip connection of the semiconductor chip, etc. Also, it is preferable that the first and second notched opening portions Cx, Cy of the solder resist 20 should be provided on both sides of all connection pads P. But such first and second notched opening portions Cx, Cy may be provided partially in any positions.

In the example in FIG. 4, the shape of the first and second notched opening portions Cx, Cy of the solder resist 20 is formed like a quadrangular shape. In this case, any shape such as a triangular shape, a trapezoidal shape, a semi-circular shape, or the like may be employed if such shape is dented in the horizontal direction. Therefore, various shapes can be employed.

As the wiring substrate 1, a rigid type wiring substrate in which the multilayer wiring is provided on one surface or both surfaces of an insulating substrate such as a glass epoxy resin, or the like, a flexible type wiring substrate using a polyimide film, or the like as a substrate, or the like can be employed. Otherwise, in the case that a higher density wiring substrate interposer, or the like) is constructed, the multilayer wiring may be formed on one surface or both surfaces of a silicon substrate.

Also, in the example in FIG. 4, the opening portions 20a of the solder resist 20 are formed to be connected like the frame. In this case, the opening portions 20a each having an extending shape (an elongated shape) may be arranged to be divided to the four sides. Also, the shape of the connection pad P is depicted with a straight shape over the whole. But a pad part whose width is expanded wider than other parts may be provided in the center part.

The arrangement of the connection pads P and the shapes of the opening portions 20a of the solder resist 20 are not restricted to their illustrated ones. Any mode may be employed if the opening portion 20a of the solder resist 20 is set to any shape such as an extending shape extended in a required direction, or, the like and then a plurality of connection pads P may be arranged in the opening portion 20a.

Next, a method of flip-chip connecting the semiconductor chip to the wiring substrate 1 according to the present embodiment will be explained hereunder. As depicted in FIG. 5, a sealing resin material 30a is formed on the wiring substrate 1. The wiring substrate 1 depicted in FIG. 5 corresponds to a section taken along I-I in the partially enlarged plan view of FIG. 4.

As the sealing resin material 30a, an epoxy resin, or the like is used. A resin film kept in a semi-cured state (B stage) may be arranged, or a liquid resin may be coated.

Then, a semiconductor chip 40 (an LSI chip) having bump electrodes 42 on the lower surface side is prepared. The bump electrodes 42 of the semiconductor chip 40 are aligned so as to correspond to the connection pads P of the wiring substrate 1 described above.

In the example of the present embodiment, the bump electrodes 42 of the semiconductor chip 40 are made of gold (Au). The bump electrodes 42 of the semiconductor chip 40 are pushed into the sealing resin material 30a on the wiring substrate 1, thereby the bump electrodes 42 of the semiconductor chip 40 are pressure-welded to the connection pads P of the wiring substrate 1.

Then, as depicted in FIG. 6, the solder layers of the connection pads P are melted by applying the reflow heating. Thus, the bump electrodes 42 (gold) of the semiconductor chip 40 are flip-chip connected to the connection pads P of the wiring substrate 1.

When the reflow heating is applied, the sealing resin material 30a being kept in a semi-cured state is cured simultaneously, and thus a cured sealing resin 30 is filled a clearance under the semiconductor chip 40. The sealing resin 30 is also called an underfill resin. A sectional view of FIG. 6 corresponds to a section taken along II-II in a plan view of FIG. 6.

Here, in the case that the curing of the sealing resin 30 given by the reflow heating only is not enough, the sealing resin 30 may be cured completely by applying the heating process further after the reflow heating.

Accordingly, a semiconductor device 2 of the present embodiment is obtained. When the multi production wiring substrate is used, individual semiconductor devices can be obtained by cutting the wiring substrate such that respective chip mounting areas of the wiring substrate are obtained.

In the present embodiment, such a mode is illustrated that the bump electrodes 42 of the semiconductor chip 40 are formed of gold and then are connected to the solder layers of the connection pads P of the wiring substrate 1. The bump electrodes 42 of the semiconductor chip 40 and the connection pads P of the wiring substrate 1 can be formed of various metals, and various connection methods can be employed.

For example, in addition to the gold-solder junction described above, at least the surface side of the bump electrodes 42 of the semiconductor chip 40 may be formed of the solder, and the connection pads P of the wiring substrate 1 may be formed of a copper layer.

Otherwise, the bump electrodes 42 of the semiconductor chip 40 may be formed of copper, and then may be jointed to the solder layers of the connection pads P. Alternatively, the bump electrodes 42 of the semiconductor chip 40 may be formed of a copper layer/a solder layer (surface side), and then may be jointed to the solder layers of the connection pads P.

As explained in the preliminary matter described above, in the case that the prior sealing technology is employed, the air bubbles are easily entered into the sealing resin material 30a at the time when the semiconductor chip 40 is flip-chip connected to the sealing resin material 30a. Further, when the sealing resin material 30a is cured by applying the heating process, there is a case that a gas (water vapor, or the like) generated from the wiring substrate 1 is trapped in the sealing resin 30.

In the present embodiment, as depicted in FIG. 7, the voids B occurring in the sealing resin 30 are driven into the first and second notched opening portions Cx, Cy of the solder resist 20, and are trapped therein. As a result, such a situation is prevented that the voids B occurs at the level difference parts of the connection pads P.

This is because the air bubbles entered into the sealing resin material 30a is made to move concentratedly into the outermost level difference surfaces (the first and second notched opening portions Cx, Cy) on both sidewalls of the opening portions 20a of the solder resist 20. A partially enlarged sectional view of FIG. 7 corresponds to a section taken along in a partially enlarged plan view of FIG. 7.

The voids B do not occur at the level difference parts of the connection pads P which are arranged to the sidewalls of the opening portions 20a of the solder resist 20, and void B is arranged at the position which is away from the connection pad P by at least, the distance s. By this matter, even though the voids B occur in the sealing resin 30, such a situation is obtained that the whole of the connection pads P are sealed with the sealing resin 30 certainly, and it is prevented that the voids B which contact the connection pad P occur.

Accordingly, no void B (space) which contacts the connection pad P exist. Therefore, in the HAST test described above, such a risk can be avoided that copper ions of the connection pad P dissolve to cause the copper migration. This signifies that the copper migration of the connection pad P does not occur when the semiconductor device 2 is mounted on the electronic equipment and it is used. As a result, reliability of the semiconductor device 2 can be improved.

Also, in the case that the solder layer exists on the surface side of the connection pad P, since the void B (the space) that the solder flows does not exist around the connection pad P, flowage of the solder layer caused at a time of the reflow heating can be prevented. Therefore, there is no risk of causing an electric short-circuit between the connection pads P.

Here, as described above, in the case that a quadrangular shape is used as the shape of the first and second notched opening portions Cx, Cy, it is necessary to provide the required distance s between the Connection pads P and the opening positions of the first and second notched opening portions Cx, Cy.

However, in the case that a triangular shape or a trapezoidal shape, or the like whose width is narrowed gradually toward an inner part side is used as the shape of the first and second notched opening portions Cx, Cy, even though the distance s is set to zero, the void B is arranged away from the connection pad P. Therefore, there is no necessity that the distance s should always be provided.

As explained above, in the semiconductor device 2 of the present embodiment, the bump electrodes 42 of the semiconductor chip 40 are flip-chip connected to the connection pads P of the wiring substrate described above 1 by using the prior sealing technology. Also, the sealing resin 30 is filled in the clearances located under the semiconductor chip 40.

In the semiconductor device 2 of the present embodiment, the semiconductor chip 40 is flip-chip connected by using the prior sealing technology that is easy to cause the voids B in the sealing resin 30. When the voids B occur in the sealing resin 30, the voids B are trapped in the first and second notched opening portions Cx, Cy of the solder resist 20 of the wiring substrate 1. Therefore, such a situation can be avoided that the void B contacts the connection pad P.

As a result, reliability of the electrical connection between the connection pads P of the semiconductor device 2 and the semiconductor chip 40 can be improved.

All examples and conditional language recited herein are intended for pedagogical purpose to aid the reader in understanding the invention and the concepts contributed by the inventor to furthering the art, and are to be construed as being without limitation to such specifically recited examples and conditions, nor does the organization of such examples in the specification relates to a showing of the superiority and interiority of the invention. Although the embodiments of the present invention have been described in detail, it should be understood that the various changes, substitutions, and alterations could be made hereto without departing from the spirit and scope of the invention.

1. A wiring substrate, comprising:
a plurality of connection pads; and
a protection insulating layer in which opening portion exposing said plurality of connection pads collectively is provided;
wherein a notched opening portion is provided to a sidewall of the opening portion of the protection insulating layer in area between said plurality of connection pads.

2. A wiring substrate according to claim 1, wherein the opening portion of the protection insulating layer has an extending shape extended in a required direction, said plurality of connection pads are arranged perpendicularly to an extending direction of the opening portion, and the notched opening portion is provided on both sidewalls of the opening portion of the protection insulating layer respectively.

3. A wiring substrate according to claim 1, wherein a required distance is provided between an opening position of the notched opening portion provided in the protection insulating layer and the connection pad.

4. A wiring substrate according to claim 1, wherein the connection pads are formed of a copper layer or a copper layer on a surface side of which a solder layer is formed.

5. A semiconductor device, comprising:
the wiring substrate set forth in claim 1;
a semiconductor chip flip-chip connected to the connection pads P of the wiring substrate; and
a sealing resin filled between the semiconductor chip and the wiring substrate.

6. A method of manufacturing a semiconductor device, comprising:
forming a sealing resin material on a wiring substrate, the wiring substrate including a plurality of connection pads, and a protection insulating layer in which opening portion exposing said plurality of connection pads collectively is provided, and a notched opening portion is provided to a sidewall of the opening portion in the protection insulating layer in area between said plurality of connection pads; and
pushing bump electrodes of a semiconductor chip into the sealing resin material to flip-chip connect the bump electrodes to the connection pads, and filling a sealing resin formed of the sealing resin material under the semiconductor chip.

7. A method of manufacturing a semiconductor device, according to claim 6, wherein, in the flip-chip connecting of the semiconductor chip, a void occurring in the sealing resin is trapped in the notched opening portion of the protection insulating layer.

8. A method of manufacturing a semiconductor device, according to claim 6, wherein the connection pads are formed of a copper layer or a copper layer on a surface side of which a solder layer is formed.

9. A semiconductor device, comprising:
the wiring substrate set forth in claim 2;
a semiconductor chip flip-chip connected to the connection pads P of the wiring substrate; and
a sealing resin filled between the semiconductor chip and the wiring substrate.

10. A semiconductor device, comprising:
the wiring substrate set forth in claim 3;
a semiconductor chip flip-chip connected to the connection pads P of the wiring substrate; and
a sealing resin filled between the semiconductor chip and the wiring substrate.

11. A semiconductor device, comprising:
the wiring substrate set forth in claim 4;
a semiconductor chip flip-chip connected to the connection pads P of the wiring substrate; and
a sealing resin filled between the semiconductor chip and the wiring substrate.
